(19) United States
(12) Patent Application Publication
(10) Pub. No.: US 2026/0371479 A1
(43) Pub. Date: Nov. 19, 2026

(54) WINDING FIXTURE, ELECTRO-OPTICAL DEVICE PACKAGING STRUCTURE AND ELECTRO-OPTICAL DEVICE

(71) Applicant: BROWAVE CORPORATION, Hsinchu County (TW)

(72) Inventor: HUNG-KUANG HSU, Hsin-Chu Conty (TW)

(21) Appl. No.: 19/282,016

(22) Filed: Jul. 28, 2025

(30) Foreign Application Priority Data
May 13, 2025 (TW) 114117943

(51) Int. Cl. H05K 1/02

(52) U.S. Cl. CPC H05K 1/0274; H05K 2201/10356

(57) ABSTRACT

A winding fixture has a winding base and a connector base. The winding base has a base, wire-receiving structures and a circuit board fixing structure. The wire-receiving structures are formed on the upper surface of the base, and the circuit substrate fixing structure is formed on the lower surface of the base. One end of the connector base is rotatably connected to one end of the winding base, and another end of the connector bass has connector receiving structures. The circuit substrate fixing structure fixes a circuit board of an electro-optical module to the winding base, the wire-receiving structures define a winding space on the upper surface of the base. The winding space cooperates with the wire-receiving structures to allow the wires of the electro-optical module to be wound within the winding space, and the connector receiving structures accommodate and fix connectors connected to the wirings.

### CROSS REFERENCE

The present disclosure claims a priority of a TW patent application 114117943, which is filed on May 13, 2025, wherein all contents of the reference which priority is claimed by the present patent application are included in the present patent application, herein.

### BACKGROUND

### Technical Field

The present disclosure relates to an electro-optical device packaging structure, and in particularly to, a winding fixture that makes a wiring connector (for example, but not limited to, an optical fiber connector) be able to rotate and allows a plurality of wirings (for example, but not limited to, optical fibers) to be wound, as well as an electro-optical device packaging structure and an electro-optical device, both including the winding fixture.

### Related Art

An electro-optical device is typically a component used for converting electrical signals into optical signals and is primarily utilized in optical communication networks. An electro-optical device generally includes a circuit board, an electro-optical conversion component, an optical fiber array, and a wavelength division multiplexer. The optical fiber array is connected to a plurality of optical fibers, and the wavelength division multiplexer and a plurality of optical fiber connectors are also connected to the plurality of optical fibers.

In consideration of matching and transmission performance, the lengths of the plurality of optical fibers are often different, which leads to difficulties in wire winding and assembly. Furthermore, after wire winding, the plurality of optical fibers with unequal lengths may result in inconsistent bending, thereby affecting the optical coupling characteristics of the electro-optical device. In addition, due to the wire winding process, the optical fiber connectors may become unstable in alignment, making it difficult to ensure the performance characteristics of the electro-optical module.

### SUMMARY

It can be understood from the foregoing description that an object of the present disclosure is to provide a winding fixture and an electro-optical device packaging structure and electro-optical device including the winding fixture, so as to solve the aforementioned technical problems.

According to one object of the preset disclosure, an exemplary embodiment of the present disclosure provides a winding fixture comprising a winding base and a connector base. The winding base has a base, a plurality of first wire-receiving structures, a second wire-receiving structure, and a circuit board fixing structure. The plurality of first wire-receiving structures are formed on a first surface of the base, the circuit board fixing structure is formed on a second surface of the base, and the second surface of the base is opposite to the first surface of the base. The connector base has one end being rotatably connected to one end of the winding base, and further has another end which comprises a plurality of connector-receiving structures. The circuit board fixing structure is configured to fix a circuit board of an electro-optical module to the winding base. The plurality of first wire-receiving structures define a winding space on the first surface of the base. The winding space cooperates with the plurality of first wire-receiving structures to allow a plurality of wirings of the electro-optical module to be wound within the winding space. The second wire-receiving structure is used to hook and hold the plurality of wirings after winding within the winding space. The plurality of connector-receiving structures are used to accommodate and fix a plurality of wiring connectors connected to the plurality of wirings.

Optionally, in one exemplary embodiment, the other end of the connector base further extends to form two fixing parts which are opposite to each other, and the two fixing parts cooperate with a fastening member to secure the winding fixture within an accommodation space of an electro-optical device packaging box.

Optionally, in one exemplary embodiment, the end of the winding base extends toward opposite sides to form two shaft components, the end of the connector base is formed with two claw-shaped pivot members which are opposite to each other, and the two claw-shaped pivot members are pivotally connected to the two shaft components, thereby allowing the end of the connector base to be rotatably and detachably connected to the end of the winding base.

Optionally, in one exemplary embodiment, each of the plurality of connector-receiving structures is recessed to form a receiving space for accommodating the wiring connector, and one end of the connector-receiving structure is formed with a wiring connector locking part for securing the wiring connector within the receiving space.

Optionally, in one exemplary embodiment, the circuit board fixing structure comprises an engaging member, two oppositely disposed first retaining walls, and a second retaining wall disposed adjacent to the two first retaining walls. The engaging member is connected to and protrudes from the second retaining wall, and is configured to engage the circuit board. When the circuit board is engaged with the winding base, a first side of the circuit board is configured to abut against the second retaining wall, and two second sides of the circuit board, which are adjacent to the first side, are configured to abut against the two first retaining walls.

Optionally, in one exemplary embodiment, the plurality of first wire-receiving structures are two first wire-receiving structures that equal in length and are symmetrically disposed on opposite sides of the base, and the second wire-receiving structure is disposed between the two opposite sides of the base, and cooperates with one side of the base to define an optical component housing space configured to accommodate an optical component connected to the plurality of wirings of the electro-optical module.

Optionally, in one exemplary embodiment, the two first wire-receiving structures are two hook-shaped structures extending from opposite sides of the base, and the second wire-receiving structure is another hook-shaped structure formed on a first surface of the base and oriented toward the other side of the base.

According to one object of the preset disclosure, an exemplary embodiment of the present disclosure provides an electro-optical device packaging structure. The electro-optical device packaging structure comprises the winding fixture, the electro-optical device packaging box, the fastening member and an electro-optical device packaging cover, wherein the winding fixture has the two opposing fixing parts. The electro-optical device packaging box has an accommodation space configured to accommodate the winding fixture. The fastening member is configured to secure the winding fixture within the accommodation space of the electro-optical device packaging box. The electro-optical device packaging cover is configured to cover the electro-optical device packaging box.

According to one object of the preset disclosure, an exemplary embodiment of the present disclosure provides an electro-optical device. The electro-optical device comprises the winding fixture and the electro-optical module, wherein the winding fixture has the two opposing fixing parts, and the electro-optical module has the circuit board fixed to the winding base.

Optionally, in one exemplary embodiment, the circuit board has an optical fiber array, the plurality of wirings are a plurality of optical fibers, two of the plurality of wirings are connected to the optical fiber array and two of the plurality of wiring connectors, one of the plurality of wirings is connected to the optical fiber array and a wavelength division multiplexer, and the other two of the plurality of wirings are connected to the wavelength division multiplexer and the other two of the plurality of wiring connectors.

Optionally, in one exemplary embodiment, the electro-optical device further comprises the electro-optical device packaging box, the fastening member, and an electro-optical device packaging cover. The electro-optical device packaging box has the accommodation space configured to accommodate the winding fixture. The fastening member is configured to secure the winding fixture within the accommodation space of the electro-optical device packaging box. The electro-optical device packaging cover is configured to cover the electro-optical device packaging box.

As described above, compared to the prior art, the winding fixture provided by the present disclosure makes the wiring connector fixed to the connector base be able to mate with an external wiring connector with improved coupling efficiency, and also allows a plurality of wirings of unequal lengths to be wound for wire winding, thereby ensuring stable characteristics of the electro-optical device.

### BRIEF DESCRIPTION OF DRAWINGS

FIG. 1 is a perspective view of a winding fixture according to an embodiment of the present disclosure.

FIG. 2 is another perspective view of the winding fixture according to an embodiment of the present disclosure.

FIG. 3 is a schematic view illustrating a scenario in which an electro-optical module is mounted on the winding fixture, according to an embodiment of the present disclosure.

FIG. 4 is a perspective view showing the electro-optical module fixed to the winding fixture according to an embodiment of the present disclosure.

FIG. 5 is a perspective view of the winding fixture and its fixed electro-optical module placed on a carrier stage, according to an embodiment of the present disclosure.

FIG. 6 is a perspective view of an electro-optical device according to an embodiment of the present disclosure.

FIG. 7 is a perspective view of an electro-optical device packaging box according to an embodiment of the present disclosure.

FIG. 8 is a schematic view illustrating a scenario in which the winding fixture and its fixed electro-optical module are secured within the electro-optical device packaging box, according to an embodiment of the present disclosure.

FIG. 9 is a perspective view of the electro-optical device according to an embodiment of the present disclosure.

FIG. 10 is a schematic view illustrating a scenario in which the electro-optical device is disassembled according to an embodiment of the present disclosure.

### DETAILS OF EXEMPLARY EMBODIMENTS

The present disclosure provides a winding fixture, as well as an electro-optical device packaging structure and an electro-optical device, both of which include the winding fixture. By employing a rotatable connector base, the wiring connector fixed to the connector base can achieve better coupling efficiency when mating with an external wiring connector. Additionally, the winding base is designed with a plurality of wire-receiving structures and a winding space, allowing a plurality of wirings of unequal lengths to be wound around the wire-receiving structures for organized routing. This enables a single routing path and ensures the stable characteristics of the electro-optical device. The following provides a detailed description of exemplary embodiments of the present disclosure with reference to the accompanying drawings. It should be noted, however, that the following implementation details are not intended to limit the scope of the present disclosure, but are provided solely to facilitate understanding by those skilled in the art.

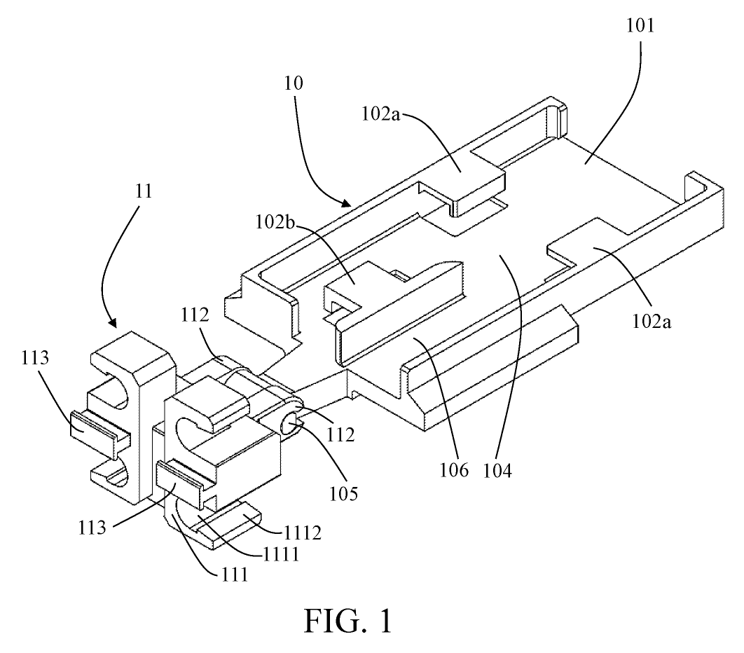

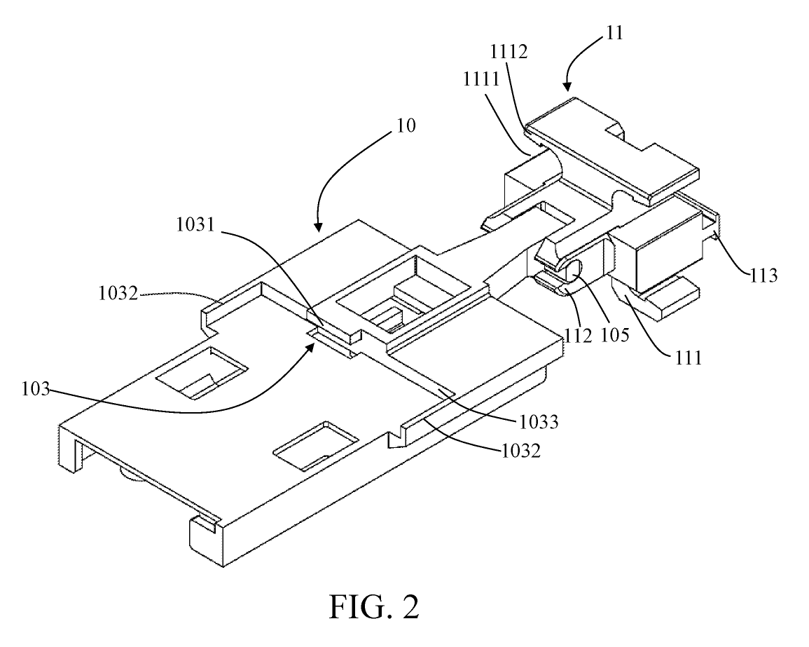

Refer to FIGS. 1 and 2, FIG. 1 is a perspective view of a winding fixture according to an embodiment of the present disclosure, and FIG. 2 is another perspective view of the winding fixture according to an embodiment of the present disclosure. The winding fixture of the present disclosure includes a winding base 10 and a connector base 11. The winding base 10 comprises a base 101, a plurality of first wire-receiving structures 102a, a second wire-receiving structure 102b, and a circuit board fixing structure 103. The plurality of first wire-receiving structures 102a and the second wire-receiving structure 102b are formed on a first surface (upper surface) of the base 101, while the circuit board fixing structure 103 is formed on a second surface (lower surface) of the base 101, wherein the second surface of the base 101 is opposite to the first surface of the base 101.

One end (front end) of the connector base 11 is rotatably connected to one end (rear end) of the winding base 10. Another end (rear end) of the connector base 11 is provided with a plurality of connector-receiving structures 111. Furthermore, one end (rear end) of the winding base 10 extends toward opposite sides to form two shaft components 105. One end (front end) of the connector base 11 is formed with two opposing claw-shaped pivot members 112. The two claw-shaped pivot members 112 are pivotally connected to the two shaft components 105, allowing the end (front end) of the connector base 11 to be rotatably and detachably connected to the end (rear end) of the winding base 10. If the plurality of connector-receiving structures 111 of the currently used connector base 11 are not compatible with the types of the present wiring connectors 22, the currently used connector base 11 can be detached and replaced with another connector base 11 that is suitable for the types of the plurality of present wiring connectors 22.

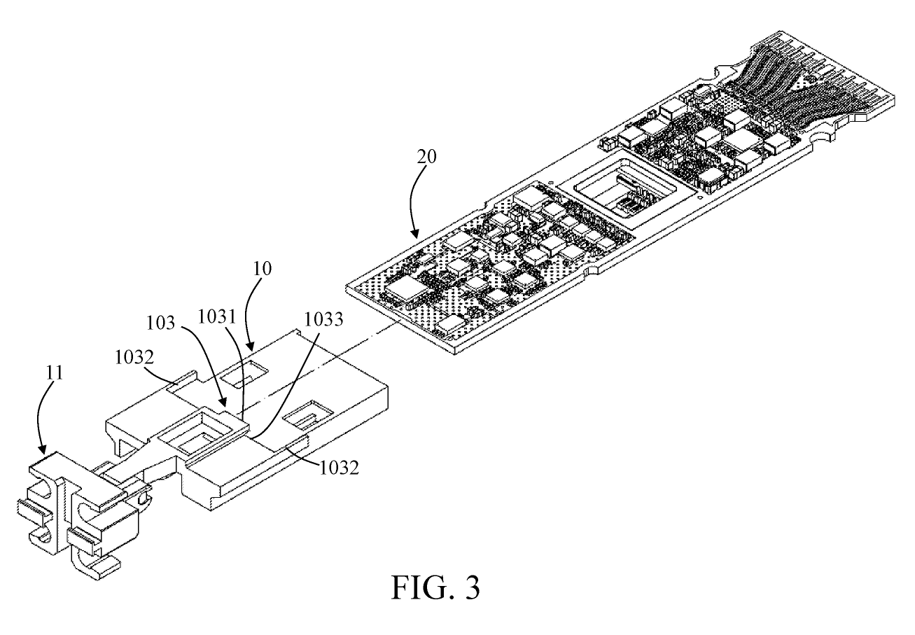

Refer to FIGS. 2 and 3, and FIG. 3 is a schematic view illustrating a scenario in which an electro-optical module is mounted on the winding fixture, according to an embodiment of the present disclosure. The circuit board fixing structure 103 is used to fix the circuit board 20 of the electro-optical module to the winding base 10. Furthermore, the circuit board fixing structure 103 includes an engaging member 1031, two oppositely disposed first retaining walls 1032, and a second retaining wall 1033 disposed adjacent to the two first retaining walls 1032. The engaging member 1031 is connected to the second retaining wall 1033 and protrudes from the second retaining wall 1033, and is configured to engage the circuit board 20. When the circuit board 20 is engaged with the winding base 10, a first side (rear side) of the circuit board 20 abuts against the second retaining wall 1033, and two second sides (left and right sides) adjacent to the first side (rear side) of the circuit board 20 abut against the two first retaining walls 1032.

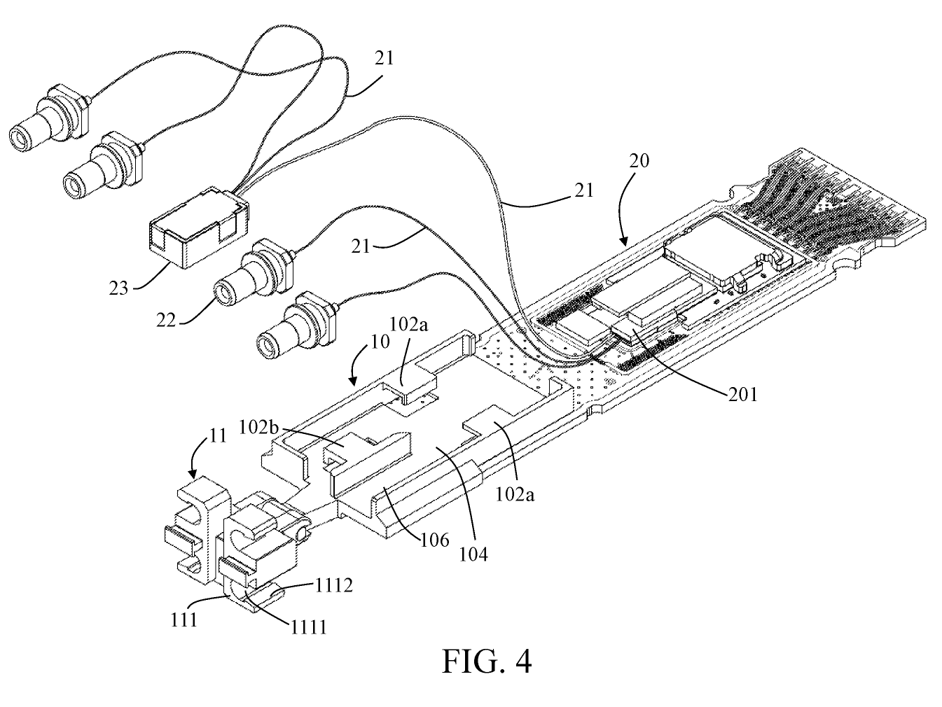

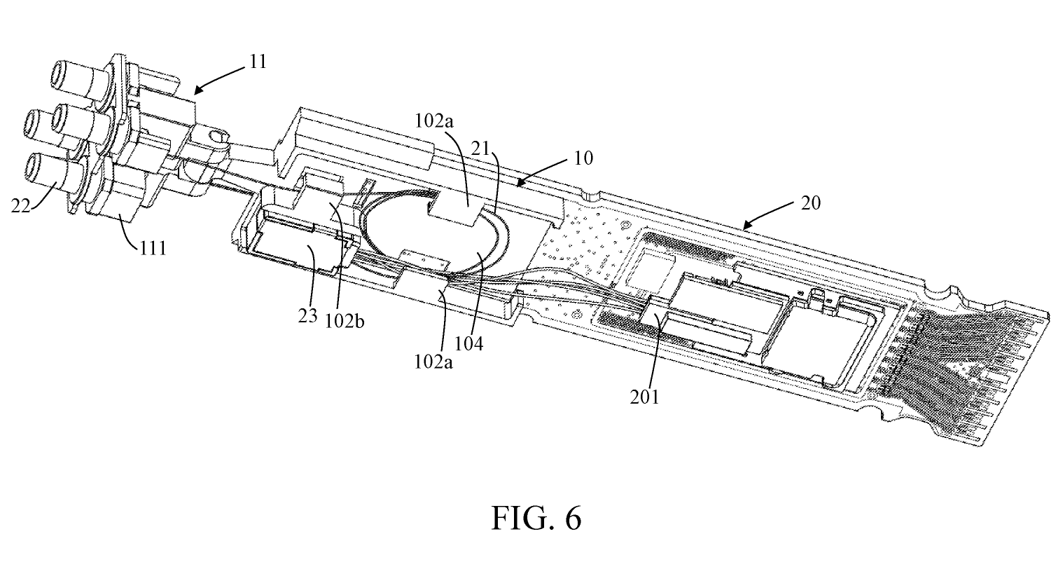

Refer to FIGS. 1,4 and 6, FIG. 4 is a perspective view showing the electro-optical module fixed to the winding fixture according to an embodiment of the present disclosure, and FIG. 6 is a perspective view of an electro-optical device according to an embodiment of the present disclosure. The plurality of first wire-receiving structures 102a define a winding space 104 on the first surface (upper surface) of the base 101. The winding space 104 cooperates with the plurality of first wire-receiving structures 102a to allow a plurality of wirings 21 of the electro-optical module to be wound within the winding space 104 for wire winding (i.e., the plurality of wirings 21 are wound around the plurality of first wire-receiving structures 102a within the winding space 104 for wire winding). The second wire-receiving structure 102b is used to hook and hold the plurality of wirings 21 after they are wound within the winding space 104.

Additionally, the plurality of connector-receiving structures 111 are used to accommodate and secure the plurality of wiring connectors 22 that are connected to the plurality of wirings 21. Furthermore, each of the connector-receiving structures 111 is recessed to form a receiving space 1111 for housing a wiring connector 22, and one end of the connector-receiving structure 111 is formed with a wiring connector locking part 1112 to secure the wiring connector 22 within the receiving space 1111. It is worth noting that, in some examples, the types of the plurality of wiring connectors 22 do not necessarily have to be completely different; for example, some may be LC connectors and others may be RCP connectors.

In the embodiment, the plurality of first wire-receiving structures 102a are two first wire-receiving structures 102a, which are of equal length and symmetrically aligned on opposite sides (left and right sides) of the base 101. A second wire-receiving structure 102b is disposed between the two sides of the base 101 and defines, together with one side of the base 101 (e.g., the right side), an optical component housing space 106 for accommodating an optical component 23 connected to the plurality of wirings 21 of the electro-optical module, such as, but not limited to, a wavelength division multiplexer. By disposing the two first wire-receiving structures 102a of equal length and in symmetrical alignment on opposite sides of the base 101, and using the second wire-receiving structure 102b to retain the plurality of wirings 21 after being wound in the winding space 104, optical loss can be reduced and optical coupling efficiency can be increased.

In addition, the two first wire-receiving structures 102a disposed on the opposite sides (left and right sides) of the base 101 are two hook-shaped structures extending from the opposite sides of the base 101. The second wire-receiving structure 102b, which is disposed between the opposite sides (left and right sides) of the base 101, is another hook-shaped structure formed on the first surface (upper surface) of the base 101 and oriented toward the other side of the base 101 (e.g., the left side).

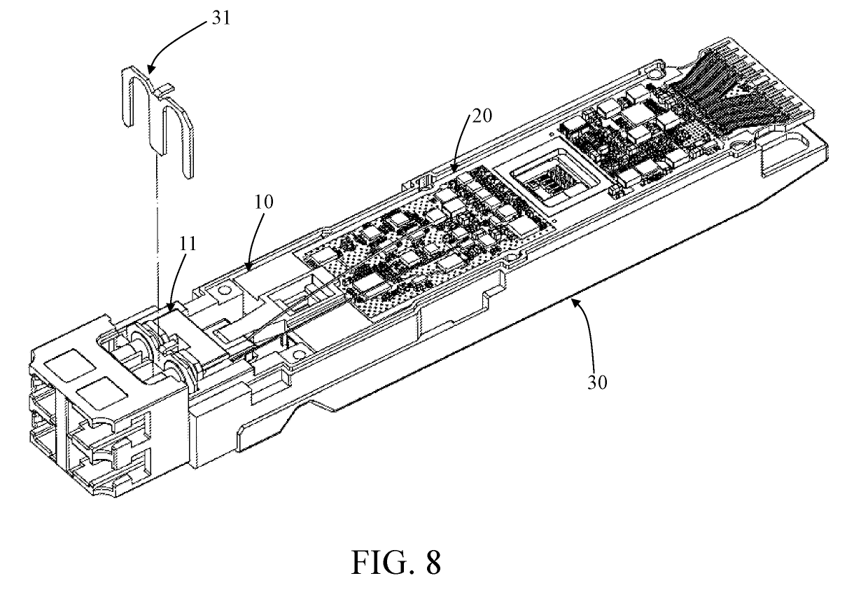

Refer to FIGS. 1, 7 and 8, FIG. 7 is a perspective view of an electro-optical device packaging box according to an embodiment of the present disclosure, and FIG. 8 is a schematic view illustrating a scenario in which the winding fixture and its fixed electro-optical module are secured within the electro-optical device packaging box, according to an embodiment of the present disclosure. The other end (rear end) of the connector base 11 further extends to form two opposing fixing parts 113. These two fixing parts 113 cooperate with a fastening member 31 to secure the winding fixture within the accommodation space 301 of the electro-optical device packaging box 30. In this embodiment, the fixing parts 113 are designed in a T-shape, and the fastening member 31 is correspondingly designed in an M-shape. However, the present disclosure is not limited thereto. The specific design primarily depends on the type of the wiring connector 22. As long as the shapes of the fixing parts 113 and the fastening member 31 are correspondingly designed to match the type of the wiring connector 22, the function of securing the winding fixture within the accommodation space 301 of the electro-optical device packaging box 30 can be effectively achieved.

Refer to FIGS. 4 and 6. The present disclosure provides an electro-optical device, which includes an electro-optical module and a winding fixture. The electro-optical module comprises a circuit board 20, a plurality of wirings 21, a plurality of wiring connectors 22, and an optical component 23. The circuit board 20 is equipped with an electro-optical converter and an optical fiber array 201 connected to the electro-optical converter. The plurality of wirings 21 may be optical fibers, and the plurality of wiring connectors 22 may be optical fiber connectors. The circuit board 20 of the electro-optical module is fixed to the winding base 10. Furthermore, two of the wirings 21 are connected between the optical fiber array 201 and two of the wiring connectors 22. One of the wirings 21 is connected between the optical fiber array 201 and the optical component 23 (e.g., a wavelength division multiplexer), and the other two wirings 21 are connected between the optical component 23 (e.g., a wavelength division multiplexer) and the other two wiring connectors 22.

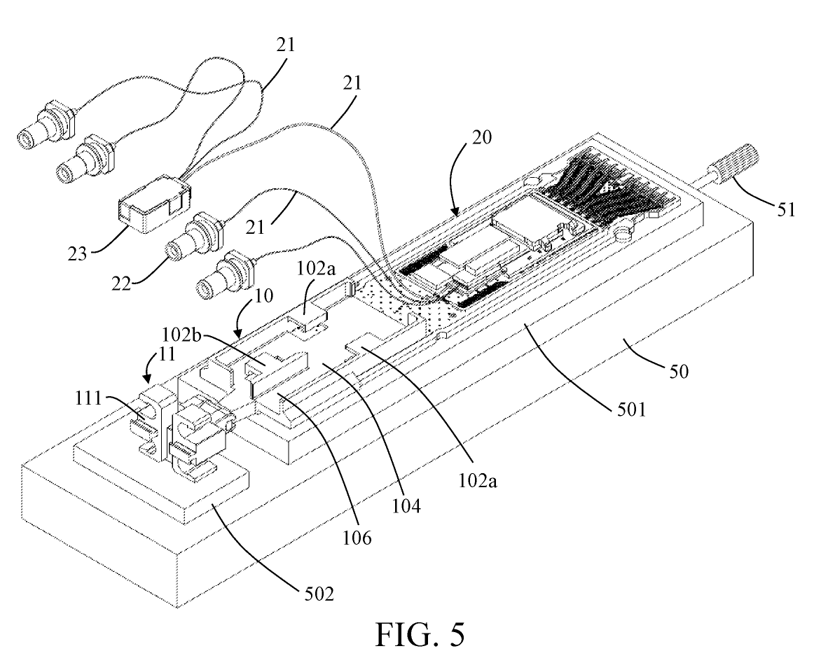

Refer to FIGS. 3-6, and FIG. 5 is a perspective view of the winding fixture and its fixed electro-optical module placed on a carrier stage, according to an embodiment of the present disclosure. The assembly of the electro-optical device is described as follows. As shown in FIG. 3, the circuit board 20 can be fixed to the winding base 10 through a circuit board fixing structure 103. As shown in FIG. 4, at this stage, the circuit board 20 has been fixed to the winding base 10, the plurality of wiring connectors 22 have not yet been secured to the plurality of connector-receiving structures 111, the plurality of wirings 21 have not yet been wound, and the optical component 23 has not yet been placed into the optical component housing space 106. Then, as shown in FIG. 5, the winding fixture and its fixed electro-optical module are placed on a carrier stage 50, wherein the carrier stage 50 includes a first carrier stage component 502 and a second carrier stage component 501 for respectively supporting the connector base 11 and the winding base 10, and further includes an adjustment component 51 for enhancing the fastening between the circuit board 20 and the winding base 10. After enhancing the fastening between the circuit board 20 and the winding base 10, the optical component 23 is placed into the optical component housing space 106, and the plurality of wirings 21 are wound within the winding space 104. The wirings 21 are firstly wound around the plurality of first wire-receiving structures 102a, and then hooked and retained by using the second wire-receiving structure 102b to complete the wire winding. Finally, the winding fixture and its fixed electro-optical module are removed from the carrier stage, thus completing the electro-optical device as shown in FIG. 6.

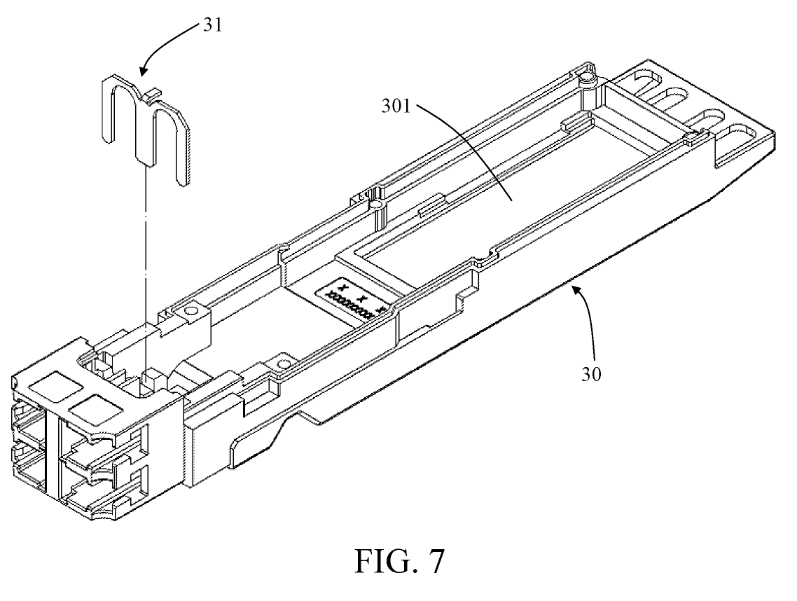

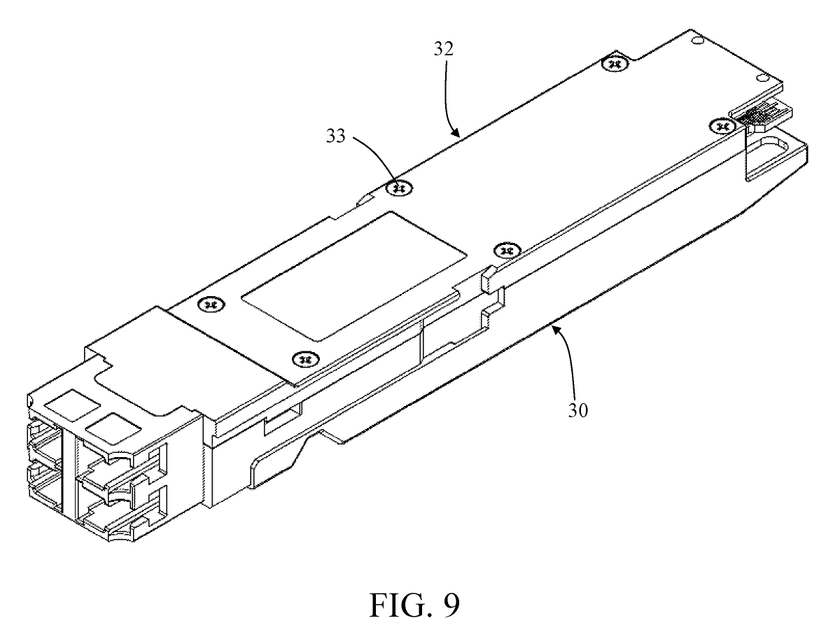

Refer to FIGS. 7 and 9, and FIG. 9 is a perspective view of the electro-optical device according to an embodiment of the present disclosure. The electro-optical device of the present disclosure further includes an electro-optical device packaging box 30, a fastening member 31, and an electro-optical device packaging cover 32. The electro-optical device packaging box 30 has an accommodation space 301 for accommodating the winding fixture. The fastening member 31 is used to secure the winding fixture within the accommodation space 301 of the electro-optical device packaging box 30. The electro-optical device packaging cover 32 is used to cover the electro-optical device packaging box 30 and includes a plurality of screw holes for a plurality of screws 33 to fasten the electro-optical device packaging cover 32 to the electro-optical device packaging box 30. Furthermore, the present disclosure also provides an electro-optical device packaging structure, which includes the winding fixture, the electro-optical device packaging box 30, the fastening member 31, and the electro-optical device packaging cover 32.

As shown in FIGS. 7 and 8, the electro-optical device of FIG. 6 can be placed into the accommodation space 301 of the electro-optical device packaging box 30. Then, the fastening member 31 is used to secure the winding fixture within the accommodation space 301 of the electro-optical device packaging box 30. Subsequently, as shown in FIG. 9, the electro-optical device packaging cover 32 is used to cover the electro-optical device packaging box 30, and the plurality of screws 33 are used to fasten the electro-optical device packaging cover 32 to the electro-optical device packaging box 30, thereby completing the electro-optical device as shown in FIG. 9.

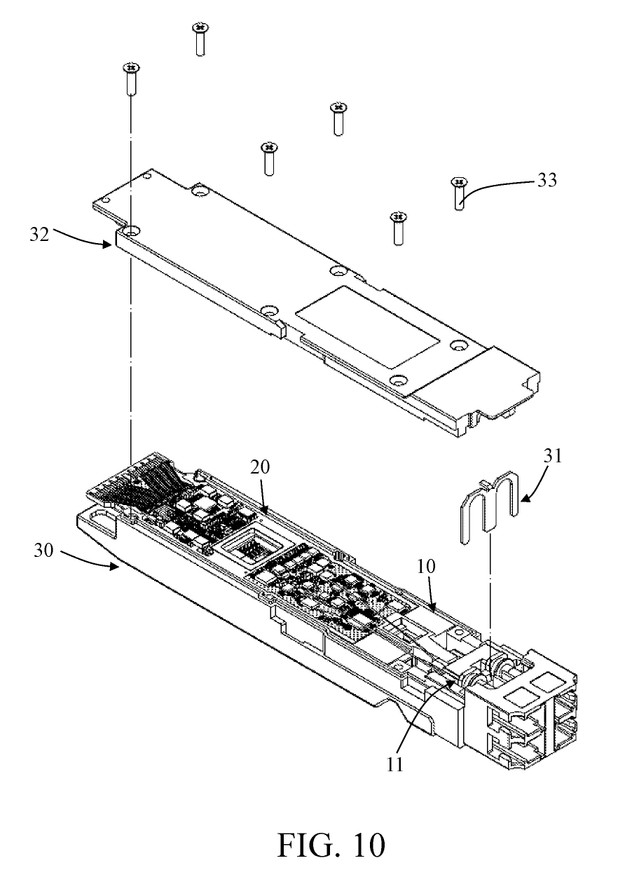

Refer to FIG. 10, and FIG. 10 is a schematic view illustrating a scenario in which the electro-optical device is disassembled according to an embodiment of the present disclosure. To disassemble the electro-optical device, the plurality of screws 33 are first removed, and the electro-optical device packaging cover 32 is taken off. Then, the fastening member 31 is removed, allowing the winding fixture and the electro-optical module to be taken out. Next, the plurality of wiring connectors 22 are detached from the connector base 11. The plurality of wound wirings 21 are unhooked from the second wire-receiving structure 102b and unwound from the plurality of first wire-receiving structures 102a to be removed from the winding space 104. The optical component 23 is also removed from the optical component housing space 106. At this point, the winding fixture and electro-optical module, as shown in FIG. 4, are obtained. Finally, the electro-optical module is removed from the winding fixture, thereby completing the disassembly of the electro-optical device.

In summary, the winding fixture provided by the present disclosure features a connector base that can rotate on a pivot shaft. This not only allows the plurality of wiring connectors connected to the plurality of wirings to be freely plugged and unplugged, but also achieves adjustment of the plurality tilt angles of the plurality of wiring connectors. As a result, the plurality of wiring connectors fixed on the connector base can smoothly mate with the plurality of external wiring connectors, achieving better coupling efficiency. Additionally, the winding base of the winding fixture provided by the present disclosure can be used to fix the circuit board of the electro-optical module and includes the plurality of wire-receiving structures and a winding space. This configuration allows the plurality of wirings of unequal lengths to be wound for wire winding, thus realizing single routing without inconsistent wiring bending. Accordingly, the stable characteristics of the electro-optical device can be ensured.

In conclusion, the winding fixture provided by the present disclosure is applicable to electro-optical devices for multi-channel and multi-connector fiber optic transmission. For connectors with different fiber lengths, the winding fixture ensures consistent wiring bending. It is suitable for integration of transmitting and receiving devices. Moreover, through the design of a pivot bearing, the assembly process avoids jamming issues and overall improves assembly process efficiency.

The foregoing description summarizes the features of the embodiments of the present disclosure so that those skilled in the art can better understand aspects of the present disclosure. Those skilled in the art should appreciate that they may readily use the present disclosure as a basis for designing or modifying other processes and structures for realizing the same purposes and/or achieving the same advantages of the embodiments introduced herein. Those skilled in the art should also recognize that such equivalent constructions do not depart from the spirit and scope of the present disclosure, and that they can be variously modified, substituted, and altered herein without departing from the spirit and scope of the present disclosure.

What is claimed is:

1. A winding fixture, comprising:
a winding base, having a base, a plurality of first wire-receiving structures, a second wire-receiving structure, and a circuit board fixing structure, wherein the plurality of first wire-receiving structures are formed on a first surface of the base, the circuit board fixing structure is formed on a second surface of the base, and the second surface of the base is opposite to the first surface of the base; and
a connector base, having one end being rotatably connected to one end of the winding base, and having another end which comprises a plurality of connector-receiving structures;
wherein the circuit board fixing structure is configured to fix a circuit board of an electro-optical module to the winding base, the plurality of first wire-receiving structures define a winding space on the first surface of the base, the winding space cooperates with the plurality of first wire-receiving structures to allow a plurality of wirings of the electro-optical module to be wound within the winding space, the second wire-receiving structure is used to hook and hold the plurality of wirings after winding within the winding space, and the plurality of connector-receiving structures are used to accommodate and fix a plurality of wiring connectors connected to the plurality of wirings.

2. The winding fixture according to claim 1, wherein the other end of the connector base further extends to form two fixing parts which are opposite to each other, and the two fixing parts cooperate with a fastening member to secure the winding fixture within an accommodation space of an electro-optical device packaging box.

3. The winding fixture according to claim 2, wherein the end of the winding base extends toward opposite sides to form two shaft components, the end of the connector base is formed with two claw-shaped pivot members which are opposite to each other, and the two claw-shaped pivot members are pivotally connected to the two shaft components, thereby allowing the end of the connector base to be rotatably and detachably connected to the end of the winding base.

4. The winding fixture according to claim 2, wherein each of the plurality of connector-receiving structures is recessed to form a receiving space for accommodating the wiring connector, and one end of the connector-receiving structure is formed with a wiring connector locking part for securing the wiring connector within the receiving space.

5. The winding fixture according to claim 2, wherein the circuit board fixing structure comprises an engaging member, two oppositely disposed first retaining walls, and a second retaining wall disposed adjacent to the two first retaining walls, the engaging member is connected to and protrudes from the second retaining wall, and is configured to engage the circuit board, and when the circuit board is engaged with the winding base, a first side of the circuit board is configured to abut against the second retaining wall, and two second sides of the circuit board, which are adjacent to the first side, are configured to abut against the two first retaining walls.

6. The winding fixture according to claim 2, wherein the plurality of first wire-receiving structures are two first wire-receiving structures that equal in length and are symmetrically disposed on opposite sides of the base, and the second wire-receiving structure is disposed between the two opposite sides of the base, and cooperates with one side of the base to define an optical component housing space configured to accommodate an optical component connected to the plurality of wirings of the electro-optical module.

7. The winding fixture according to claim 6, wherein the two first wire-receiving structures are two hook-shaped structures extending from opposite sides of the base, and the second wire-receiving structure is another hook-shaped structure formed on a first surface of the base and oriented toward the other side of the base.

8. An electro-optical device packaging structure, comprising:
a winding fixture, comprising:
a winding base, having a base, a plurality of first wire-receiving structures, a second wire-receiving structure, and a circuit board fixing structure, wherein the plurality of first wire-receiving structures are formed on a first surface of the base, the circuit board fixing structure is formed on a second surface of the base, and the second surface of the base is opposite to the first surface of the base; and
a connector base, having one end being rotatably connected to one end of the winding base, and having another end which comprises a plurality of connector-receiving structures;
wherein the circuit board fixing structure is configured to fix a circuit board of an electro-optical module to the winding base, the plurality of first wire-receiving structures define a winding space on the first surface of the base, the winding space cooperates with the plurality of first wire-receiving structures to allow a plurality of wirings of the electro-optical module to be wound within the winding space, the second wire-receiving structure is used to hook and hold the plurality of wirings after winding within the winding space, the plurality of connector-receiving structures are used to accommodate and fix a plurality of wiring connectors connected to the plurality of wirings, the other end of the connector base further extends to form two fixing parts which are opposite to each other, and the two fixing parts cooperate with a fastening member to secure the winding fixture within an accommodation space of an electro-optical device packaging box;
the electro-optical device packaging box, having the accommodation space configured to accommodate the winding fixture;
the fastening member, configured to secure the winding fixture within the accommodation space of the electro-optical device packaging box; and
an electro-optical device packaging cover, configured to cover the electro-optical device packaging box.

9. The electro-optical device packaging structure according to claim 8, wherein the end of the winding base extends toward opposite sides to form two shaft components, the end of the connector base is formed with two claw-shaped pivot members which are opposite to each other, and the two claw-shaped pivot members are pivotally connected to the two shaft components, thereby allowing the end of the connector base to be rotatably and detachably connected to the end of the winding base.

10. The electro-optical device packaging structure according to claim 8, wherein each of the plurality of connector-receiving structures is recessed to form a receiving space for accommodating the wiring connector, and one end of the connector-receiving structure is formed with a wiring connector locking part for securing the wiring connector within the receiving space.

11. The electro-optical device packaging structure according to claim 8, wherein the circuit board fixing structure comprises an engaging member, two oppositely disposed first retaining walls, and a second retaining wall disposed adjacent to the two first retaining walls, the engaging member is connected to and protrudes from the second retaining wall, and is configured to engage the circuit board, and when the circuit board is engaged with the winding base, a first side of the circuit board is configured to abut against the second retaining wall, and two second sides of the circuit board, which are adjacent to the first side, are configured to abut against the two first retaining walls.

12. The electro-optical device packaging structure according to claim 8, wherein the plurality of first wire-receiving structures are two first wire-receiving structures that equal in length and are symmetrically disposed on opposite sides of the base, and the second wire-receiving structure is disposed between the two opposite sides of the base, and cooperates with one side of the base to define an optical component housing space configured to accommodate an optical component connected to the plurality of wirings of the electro-optical module.

13. The electro-optical device packaging structure according to claim 12, wherein the two first wire-receiving structures are two hook-shaped structures extending from opposite sides of the base, and the second wire-receiving structure is another hook-shaped structure formed on a first surface of the base and oriented toward the other side of the base.

14. An electro-optical device, comprising:
a winding fixture, comprising:
a winding base, having a base, a plurality of first wire-receiving structures, a second wire-receiving structure, and a circuit board fixing structure, wherein the plurality of first wire-receiving structures are formed on a first surface of the base, the circuit board fixing structure is formed on a second surface of the base, and the second surface of the base is opposite to the first surface of the base; and
a connector base, having one end being rotatably connected to one end of the winding base, and having another end which comprises a plurality of connector-receiving structures;
wherein the circuit board fixing structure is configured to fix a circuit board of an electro-optical module to the winding base, the plurality of first wire-receiving structures define a winding space on the first surface of the base, the winding space cooperates with the plurality of first wire-receiving structures to allow a plurality of wirings of the electro-optical module to be wound within the winding space, the second wire-receiving structure is used to hook and hold the plurality of wirings after winding within the winding space, the plurality of connector-receiving structures are used to accommodate and fix a plurality of wiring connectors connected to the plurality of wirings, the other end of the connector base further extends to form two fixing parts which are opposite to each other, and the two fixing parts cooperate with a fastening member to secure the winding fixture within an accommodation space of an electro-optical device packaging box; and
the electro-optical module, having the circuit board fixed to the winding base.

15. The electro-optical device according to claim 14, wherein the circuit board has an optical fiber array, the plurality of wirings are a plurality of optical fibers, two of the plurality of wirings are connected to the optical fiber array and two of the plurality of wiring connectors, one of the plurality of wirings is connected to the optical fiber array and a wavelength division multiplexer, and the other two of the plurality of wirings are connected to the wavelength division multiplexer and the other two of the plurality of wiring connectors.

16. The electro-optical device according to claim 14, further comprising:
the electro-optical device packaging box, having the accommodation space configured to accommodate the winding fixture;
the fastening member, configured to secure the winding fixture within the accommodation space of the electro-optical device packaging box; and
an electro-optical device packaging cover, configured to cover the electro-optical device packaging box.

17. The electro-optical device according to claim 14, wherein the end of the winding base extends toward opposite sides to form two shaft components, the end of the connector base is formed with two claw-shaped pivot members which are opposite to each other, and the two claw-shaped pivot members are pivotally connected to the two shaft components, thereby allowing the end of the connector base to be rotatably and detachably connected to the end of the winding base.

18. The electro-optical device according to claim 14, wherein each of the plurality of connector-receiving structures is recessed to form a receiving space for accommodating the wiring connector, and one end of the connector-receiving structure is formed with a wiring connector locking part for securing the wiring connector within the receiving space.

19. The electro-optical device according to claim 14, wherein the circuit board fixing structure comprises an engaging member, two oppositely disposed first retaining walls, and a second retaining wall disposed adjacent to the two first retaining walls, the engaging member is connected to and protrudes from the second retaining wall, and is configured to engage the circuit board, and when the circuit board is engaged with the winding base, a first side of the circuit board is configured to abut against the second retaining wall, and two second sides of the circuit board, which are adjacent to the first side, are configured to abut against the two first retaining walls.

20. The electro-optical device according to claim 14, wherein the plurality of first wire-receiving structures are two first wire-receiving structures that equal in length and are symmetrically disposed on opposite sides of the base, the second wire-receiving structure is disposed between the two opposite sides of the base, and cooperates with one side of the base to define an optical component housing space configured to accommodate an optical component connected to the plurality of wirings of the electro-optical module, the two first wire-receiving structures are two hook-shaped structures extending from opposite sides of the base, and the second wire-receiving structure is another hook-shaped structure formed on a first surface of the base and oriented toward the other side of the base.
